(19) United States
(12) Patent Application Publication
(10) Pub. No.: US 2009/0205710 A1
(43) Pub. Date: Aug. 20, 2009

(54) Thin film type solar cell and method for manufacturing the same

(76) Inventors: Jae-Ho Kim, Yongin-si (KR); Jin Hong, Yongin-si (KR)

Correspondence Address: Royal W. Craig;Ober, Kaler, Grimes & Shriver, 120 East Baltimore Street, Baltimore, MD, 21202-1643, US

(21) Appl. No.: 12/378,891

(22) Filed: Feb. 20, 2009

(30) Foreign Application Priority Data
Feb. 20, 2008 (KR) 10-2008-0015125

(51) Int. Cl. H01L 31/0224

(52) U.S. Cl. 136/256; 438/98; 257/E31.126

(57) ABSTRACT

A thin film type solar cell and a method for manufacturing the same is disclosed, which is capable of realizing the improved efficiency in the solar cell with a decreased dead zone, wherein the method comprises forming a plurality of front electrodes on a substrate, wherein the plurality of front electrodes are formed at fixed intervals by each first separating portion interposed in-between; forming a semiconductor layer and transparent conductive layer on an entire surface of the substrate including the front electrodes; forming a contact portion being in contact with the first separating portion by removing predetermined portions of the semiconductor layer and transparent conductive layer; forming a second separating portion by removing a predetermined portion of the transparent conductive layer; and forming a rear electrode connected with the front electrode through the contact portion.

### CROSS REFERENCE TO RELATED APPLICATIONS

This application claims the benefit of the Korean Patent Application No. P2008-0015125, filed on Feb. 20, 2008, which is hereby incorporated by reference as if fully set forth herein.

### BACKGROUND OF THE INVENTION

1. Field of the Invention

The present invention relates to a thin film type solar cell, and more particularly, to a thin film type solar cell with a plurality of unit cells connected in series.

2. Discussion of the Related Art

A solar cell with a property of semiconductor converts a light energy into an electric energy.

A structure and principle of the solar cell according to the related art will be briefly explained as follows. The solar cell is formed in a PN-junction structure where a positive (P)-type semiconductor makes a junction with a negative (N)-type semiconductor. When a solar ray is incident on the solar cell with the PN-junction structure, holes (+) and electrons (−) are generated in the semiconductor owing to the energy of the solar ray. By an electric field generated in a PN-junction area, the holes (+) are drifted toward the P-type semiconductor, and the electrons (−) are drifted toward the N-type semiconductor, whereby an electric power is produced with an occurrence of electric potential.

The solar cell can be largely classified into a wafer type solar cell and a thin film type solar cell.

The wafer type solar cell uses a wafer made of a semiconductor material such as silicon. In the meantime, the thin film type solar cell is manufactured by forming a semiconductor in type of a thin film on a glass substrate.

With respect to efficiency, the wafer type solar cell is better than the thin film type solar cell. However, in the case of the wafer type solar cell, it is difficult to realize a small thickness due to difficulty in performance of the manufacturing process. In addition, the wafer type solar cell uses a high-priced semiconductor substrate, whereby its manufacturing cost is increased.

Even though the thin film type solar cell is inferior in efficiency to the wafer type solar cell, the thin film type solar cell has advantages such as realization of thin profile and use of low-priced material. Accordingly, the thin film type solar cell is suitable for a mass production.

The thin film type solar cell is manufactured by sequential steps of forming a front electrode on a glass substrate, forming a semiconductor layer on the front electrode, and forming a rear electrode on the semiconductor layer. In this case, since the front electrode corresponds to a light-incidence face, the front electrode is made of a transparent conductive material, for example, ZnO. With the increase in size of substrate, a power loss increases due to a resistance of the transparent conductive layer.

Thus, a method for minimizing the power loss has been proposed, in which the thin film type solar cell is divided into a plurality of unit cells connected in series. This method enables the minimization of power loss caused by the resistance of the transparent conductive material.

Hereinafter, a related art method for manufacturing a thin film type solar cell with a plurality of unit cells connected in series will be described with reference to FIG. 1(A to F).

FIG. 1(A to F) is a series of cross section views illustrating a related method for manufacturing a thin film type solar cell with a plurality of unit cells connected in series.

First, as shown in FIG. 1A, a front electrode layer 20a is formed on a substrate 10.

Next, as shown in FIG. 1B, a plurality of front electrodes 20 are formed by removing predetermined portions of the front electrode layer 20a through a laser-scribing process, wherein the plurality of front electrodes 20 are provided at fixed intervals by each first separating portion 25 interposed in-between.

Then, as shown in FIG. 1C, a semiconductor layer 30a and a transparent conductive layer 40a are sequentially formed on an entire surface of the substrate 10.

As shown in FIG. 1D, the plurality of semiconductor layers 30 and transparent conductive layers 40 are formed by removing predetermined portions from of the semiconductor layer 30a and transparent conductive layer 40a through a laser-scribing process, wherein the plurality of semiconductor layers 30 and transparent conductive layers 40 are provided at fixed intervals by each contact part 35 interposed in-between.

As shown in FIG. 1E, a rear electrode layer 50a is formed on the entire surface of the substrate 10.

As shown in FIG. 1F, a second separating portion 45 is formed by removing predetermined portions of the semiconductor layer 30, transparent conductive layer 40, and rear electrode layer 50a through a laser-scribing process. Thus, a plurality of rear electrodes 50 are formed at fixed intervals by each second separating portion 45 interposed in-between.

However, the related art method for manufacturing the thin film type solar cell has the following disadvantages.

First, as shown in FIG. 1F, there is a dead zone corresponding to “A” region, that is, a region from one end of the first separating portion 25 to one end of the second separating portion 45, wherein the dead zone indicates a region which can not be operated as the solar cell. In the related art, this dead zone is considerably large in size since the plurality of first separating portions 25, contact portions 35, and second separating portions 45 are formed at fixed intervals, thereby deteriorating the efficiency of solar cell.

Especially, the second separating portion 45 is formed by irradiating laser in an arrow direction of FIG. 1F. When irradiating the laser, the semiconductor layer 30a and transparent conductive layer 40 are separated by the laser, and simultaneously the rear electrode layer 50a is also separated due to an impact caused by the separation of the semiconductor layer 30 and transparent conductive layer 40. Accordingly, if the second separating portion 45 is too close to the contact portion 35, the rear electrode 50 being in contact with the front electrode 20 may be separated by the impact, thereby causing a contact failure. In this reason, if the second separating portion 45 is formed by the laser-scribing process, the second separating portion 45 should be formed at the fixed interval from the contact portion 35.

Also, the steps for forming the first separating portion 25, contact portion 35, and second separating portion 45 necessarily uses the laser-scribing process three times. During the three laser-scribing processes, the remnant that remains in the substrate may contaminate the substrate. In this respect, a cleaning process is additionally performed so as to prevent the contamination of the substrate. However, the additional cleaning process may cause complicacy and low yield.

### SUMMARY OF THE INVENTION

Accordingly, the present invention is directed to a thin film type solar cell and a method for manufacturing the same that substantially obviates one or more problems due to limitations and disadvantages of the related art.

An object of the present invention is to provide a thin film type solar cell and a method for manufacturing the same, which is capable of improving an efficiency of solar cell by decreasing a dead zone in size.

Another object of the present invention is to provide a thin film type solar cell and a method for manufacturing the same, which is capable of minimizing a possibility for contamination in a substrate by decreasing the number of performing a laser-scribing process, and is also capable of improving the yield by decreasing the number of performing a cleaning process.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a method for manufacturing a thin film type solar cell comprises forming a plurality of front electrodes on a substrate, wherein the plurality of front electrodes are formed at fixed intervals by each first separating portion interposed in-between; forming a semiconductor layer and transparent conductive layer on an entire surface of the substrate including the front electrodes; forming a contact portion being in contact with the first separating portion by removing predetermined portions of the semiconductor layer and transparent conductive layer; forming a second separating portion by removing a predetermined portion of the transparent conductive layer; and forming a rear electrode connected with the front electrode through the contact portion.

In another aspect of the present invention, a thin film type solar cell comprises a substrate; a plurality of front electrodes formed on the substrate at fixed intervals by each first separating portion interposed in-between; a plurality of semiconductor layers formed at fixed intervals by each contact portion interposed in-between, the contact portion being in contact with the first separating portion; a plurality of transparent conductive layers formed at fixed intervals by the contact portion and second separating portion; and a rear electrode connected with the front electrode through the contact portion.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 (A to F) is a series of cross section views illustrating a related method for manufacturing a thin film type solar cell;

FIG. 2 (A to F) is a series of cross section views illustrating a method for manufacturing a thin film type solar cell according to the first embodiment of the present invention;

FIG. 3 (A to F) is a series of cross section views illustrating a method for manufacturing a thin film type solar cell according to the second embodiment of the present invention;

FIG. 4 (A to F) is a series of cross section views illustrating a method for manufacturing a thin film type solar cell according to the third embodiment of the present invention;

FIG. 5 (A to F) is a series of cross section views illustrating a method for manufacturing a thin film type solar cell according to the fourth embodiment of the present invention;

FIG. 6 is a cross section view illustrating a thin film type solar cell manufactured by the first embodiment of the present invention;

FIG. 7 is a cross section view illustrating a thin film type solar cell manufactured by the second embodiment of the present invention;

FIG. 8 is a cross section view illustrating a thin film type solar cell manufactured by the third embodiment of the present invention; and

FIG. 9 is a cross section view illustrating a thin film type solar cell manufactured by the fourth embodiment of the present invention.

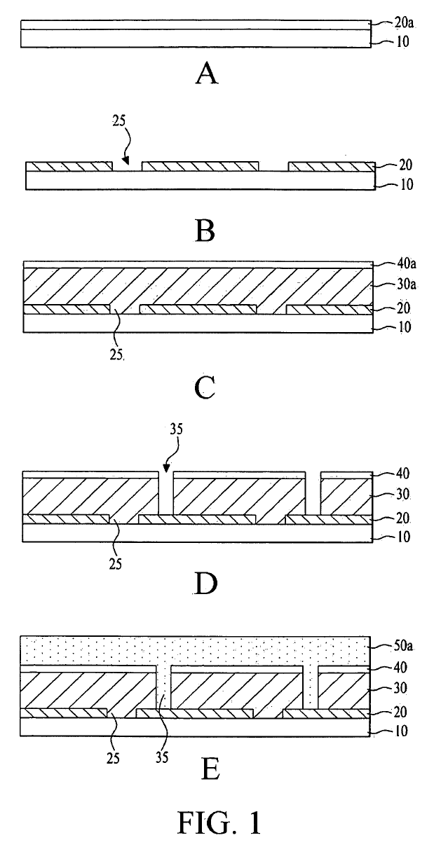

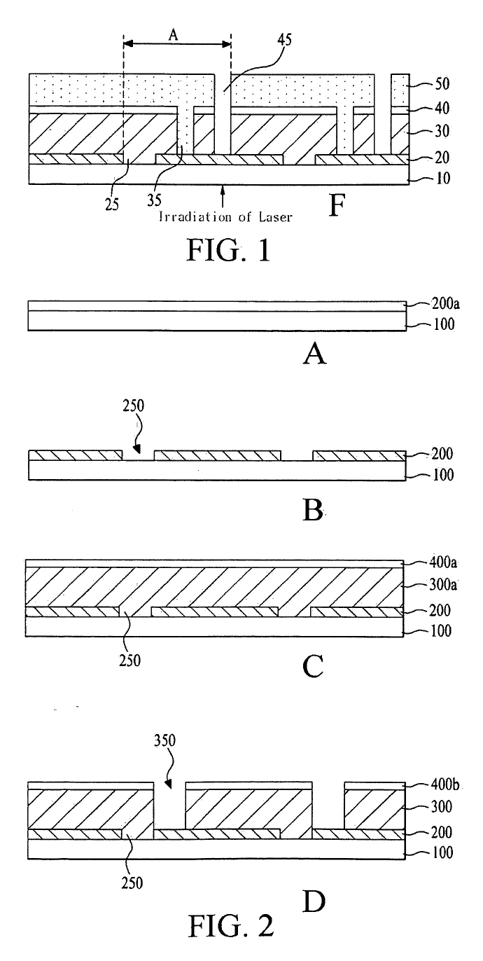

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a thin film type solar cell according to the present invention and a method for manufacturing the same will be described with reference to the accompanying drawings.

### <Method for Manufacturing Thin Film Type Solar Cell>

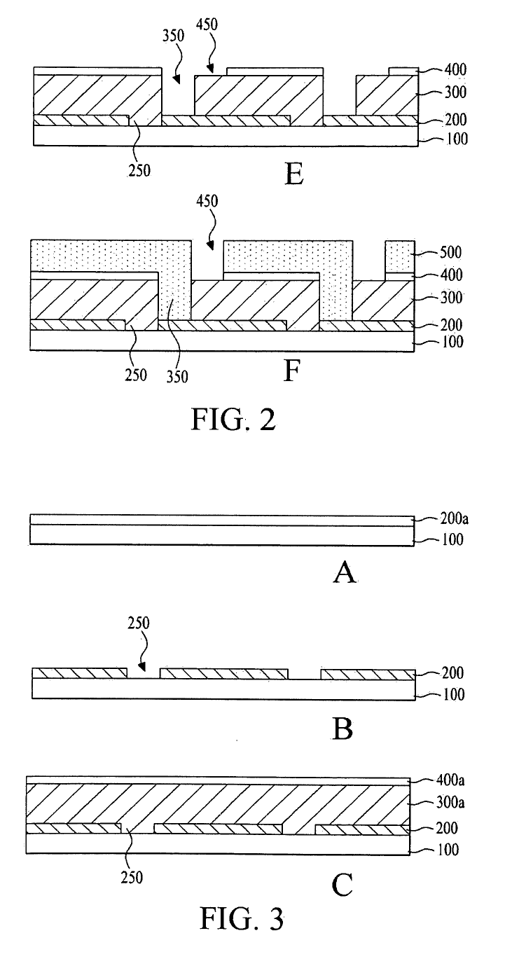

FIG. 2 (A to F) is a series of cross section views illustrating a method for manufacturing a thin film type solar cell according to the first embodiment of the present invention.

First, as shown in FIG. 2(A), a front electrode layer 200a is formed on a substrate 100.

The substrate 100 may be made of glass or transparent plastic. The front electrode layer 200a is formed of a transparent conductive material, for example, ZnO, ZnO:B, ZnO:Al, SnO₂, SnO₂:F, or ITO (Indium Tin Oxide) by sputtering or MOCVD (Metal Organic Chemical Vapor Deposition).

The front electrode layer 200a corresponds to a solar-ray incidence face. In this respect, it is important for the front electrode layer 200a to transmit solar rays into the inside of the solar cell with the increased absorption of solar ray. For this, a texturing process may be additionally applied to the front electrode layer 200a.

Through the texturing process, a surface of material layer is provided with an uneven surface, that is, a texture structure, by an etching process using photolithography, an anisotropic etching process using a chemical solution, or a mechanical scribing process. According as the texturing process is performed to the front electrode layer 200a, a solar-ray reflection ratio on the solar cell is decreased and a solar-ray absorbing ratio on the solar cell is increased owing to a dispersion of the solar ray, thereby improving the solar cell efficiency.

Next, as shown in FIG. 2(B), a first separating portion 250 is formed by removing a predetermined portion of the front electrode layer 200a. Thus, a plurality of front electrodes 200 are formed at fixed intervals by each first separating portion 250 interposed in-between.

The step for forming the first separating portion 250 may be carried out by a laser-scribing process.

Meanwhile, the plurality of front electrodes 200 may be directly formed on the substrate 100 at fixed intervals by each first separating portion 250 interposed in-between by performing a simple method such as a screen printing method, an inkjet printing method, a gravure printing method, or a micro-contact printing method, instead of applying the laser-scribing process to the front electrode layer 200a formed on an entire surface of the substrate 100 shown in FIGS. 2(A) and 2(B).

If forming the front electrodes 200 through the screen printing method, the inkjet printing method, the gravure printing method, or the micro-contact printing method, there is less worry about contamination of the substrate, in comparison to the laser-scribing process, and there is no requirement for a cleaning process to prevent contamination of the substrate.

As shown in FIG. 2(C), a semiconductor layer 300a and a transparent conductive layer 400a are sequentially formed on the entire surface of the substrate 100.

The semiconductor layer 300a may be made of a silicon-based semiconductor material by a plasma CVD method.

The semiconductor layer 300a may be formed in a PIN structure where a P-type semiconductor layer, an I-type semiconductor layer, and an N-type semiconductor layer are deposited in sequence.

In the semiconductor layer 300a with the PIN structure, depletion is generated in the I-type semiconductor layer by the P-type semiconductor layer and the N-type semiconductor layer, whereby an electric field occurs therein. Thus, electrons and holes generated by the solar ray are drifted by the electric field, and the drifted electrons and holes are collected in the N-type semiconductor layer and the P-type semiconductor layer, respectively. If forming the semiconductor layer 300a with the PIN structure, the P-type semiconductor layer is formed firstly, and then the I-type and N-type semiconductor layers are formed thereon, preferably. This is because a drift mobility of the hole is less than a drift mobility of the electron. In order to maximize the efficiency in collection of the incident light, the P-type semiconductor layer is provided adjacent to the light-incidence face.

The transparent conductive layer 400a may be formed of a transparent conductive material, for example, ZnO, ZnO:B, ZnO:Al, or Ag by sputtering or MOCVD (Metal Organic Chemical Vapor Deposition). The transparent conductive layer 400a makes the solar ray dispersed in all angles, whereby the solar ray is reflected on a rear electrode to be described, thereby resulting in the increase of solar ray re-incident on the semiconductor layer 300a.

As shown in FIG. 2(D), a contact portion 350 is formed by removing predetermined portions of the semiconductor layer 300a and transparent conductive layer 400a. Accordingly, a plurality of patterns with the semiconductor layer 300 and transparent conductive layer 400b deposited in sequence are formed at fixed intervals by each contact portion 350 interposed in-between.

At this time, the contact portion 350 is positioned in contact with the first separating portion 250. More particularly, the predetermined portions of the semiconductor layer 300a and transparent conductive layer 400a on the front electrode 200 are removed so as to meet one end of the first separating portion 250 with one end of the contact portion 350. According as one end of the first separating portion 250 meets with one end of the contact portion 350, it is possible to minimize a dead zone in the solar cell.

The step for forming the contact portion 350 may be carried out by a laser-scribing process.

As shown in FIG. 2(E), a second separating portion 450 is formed by removing a predetermined portion of the transparent conductive layer 400b. Accordingly, the plurality of transparent conductive layers 400 are patterned at fixed intervals by the contact portion 350 and second separating portion 450.

At this time, the predetermined portion of the transparent conductive layer 400b is removed so that the second separating portion 450 is in contact with the contact portion 350. According as the second separating portion 450 is in contact with the contact portion 350, it is possible to minimize the dead zone in the solar cell.

The step for forming the second separating portion 450 may be carried out by a laser-scribing process. Even though the second separating portion 450 is contact with the contact portion 350, there is no contact failure between the rear electrode and the front electrode. This is because the step for forming the second separating portion 450 is carried out before the step of forming the rear electrode.

As shown in FIG. 2(F), the rear electrode 500 is connected with the front electrode 200 through the contact portion 350.

The plurality of the rear electrodes 500 are formed at fixed intervals by each second separating portion 450 interposed in-between.

The rear electrode 500 may be formed of a metal material, for example, Ag, Al, Ag+Mo, Ag+Ni, or Ag+Cu, by a screen printing method, an inkjet printing method, a gravure printing method, or a micro-contact printing method.

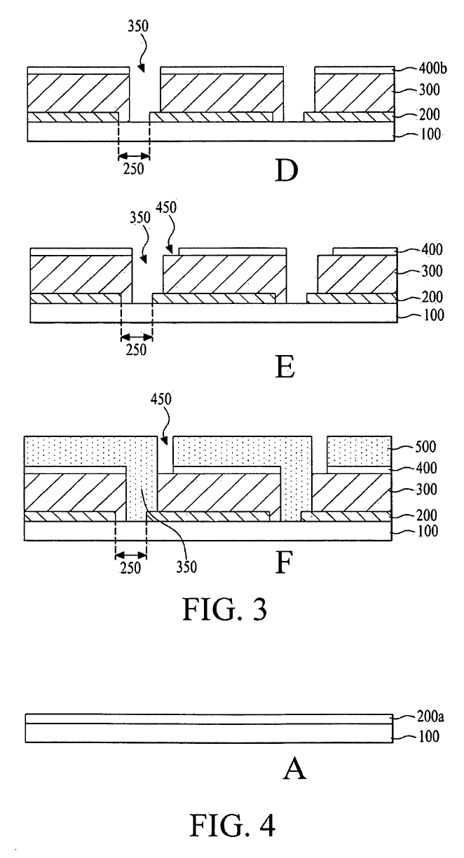

FIG. 3(A to F) is a series of cross section views illustrating a method for manufacturing a thin film type solar cell according to the second embodiment of the present invention. Except a step for forming a contact portion 350, the method for manufacturing the thin film type solar cell according to the second embodiment of the present invention is identical to the method for manufacturing the thin film type solar cell according to the first embodiment of the present invention. Wherever possible, the same reference numbers will be used throughout the drawings to refer to the same or like parts as those of the aforementioned embodiment, and the detailed explanation for the same or like parts will be omitted.

First, as shown in FIG. 3(A), a front electrode layer 200a is formed on a substrate 100.

Next, as shown in FIG. 3(B), a first separating portion 250 is formed by removing a predetermined portion of the front electrode layer 200a. Accordingly, a plurality of front electrodes 200 are formed at fixed intervals by each first separating portion 250 interposed in-between.

As shown in FIG. 3(C), a semiconductor layer 300a and a transparent conductive layer 400a are sequentially formed on an entire surface of the substrate 100.

As shown in FIG. 3(D), the contact portion 350 is formed by removing predetermined portions of the semiconductor layer 300a and transparent conductive layer 400a. Thus, a plurality of patterns with the semiconductor layer 300 and transparent conductive layer 400b deposited in sequence are formed at fixed intervals by each contact portion 350 interposed in-between.

In order to make the contact portion 350 and the first separating portion 250 partially overlapped at their predetermined portions, there is a need to remove the predetermined portions of the semiconductor layer 300a and transparent conductive layer 400a provided on the front electrode 200, and to remove the predetermined portions of the semiconductor layer 300a and transparent conductive layer 400a provided inside the first separating portion 250. Accordingly, as the contact portion 350 and the first separating portion 250 are partially overlapped at their predetermined portions, it is possible to minimize a dead zone in the solar cell. Also, since the contact portion 350 and the first separating portion 250 are partially overlapped at their predetermined portions, the upper and lateral surfaces of the front electrode 200 are exposed by the contact portion 350. Thus, a rear electrode to be described is in contact with the lateral surface of the front electrode 200 as well as the upper surface of the front electrode 200.

As shown in FIG. 3(E), a second separating portion 450 is formed by removing a predetermined portion of the transparent conductive layer 400b. Thus, the plurality of transparent conductive layers 400 are formed at fixed intervals by the contact portion 350 and second separating portion 450.

At this time, the predetermined portion of the transparent conductive layer 400b is removed so that the second separating portion 450 is in contact with the contact portion 350. According as the second separating portion 450 is provided in contact with the contact portion 350, it is possible to minimize the dead zone in the solar cell.

As shown in FIG. 3(F), the rear electrode 500 is connected with the front electrode 200 through the contact portion 350.

The plurality of the rear electrodes 500 are formed at fixed intervals by each second separating portion 450 interposed in-between.

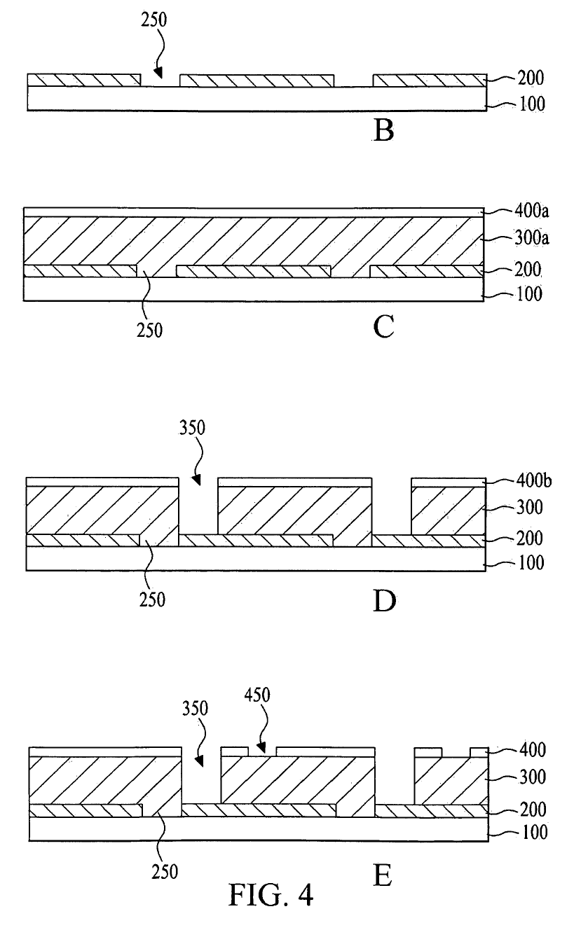

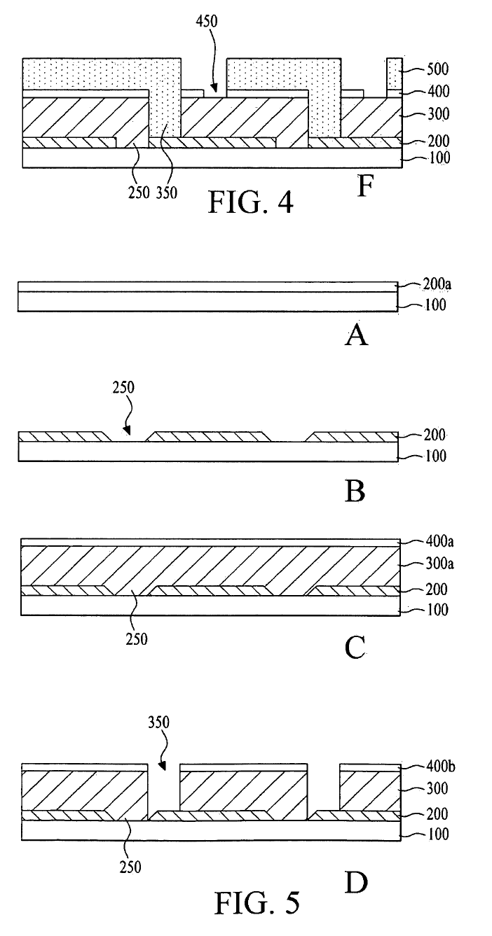

FIG. 4 (A to F) is a series of cross section views illustrating a method for manufacturing a thin film type solar cell according to the third embodiment of the present invention.

Except a step for forming a second separating portion 450, the method for manufacturing the thin film type solar cell according to the third embodiment of the present invention is identical to the method for manufacturing the thin film type solar cell according to the first embodiment of the present invention. Wherever possible, the same reference numbers will be used throughout the drawings to refer to the same or like parts as those of the aforementioned embodiment, and the detailed explanation for the same or like parts will be omitted.

First, as shown in FIG. 4(A), a front electrode layer 200a is formed on a substrate 100.

Next, as shown in FIG. 4(B), a first separating portion 250 is formed by removing a predetermined portion of the front electrode layer 200a. Accordingly, a plurality of front electrodes 200 are formed at fixed intervals by each first separating portion 250 interposed in-between.

As shown in FIG. 4(C), a semiconductor layer 300a and a transparent conductive layer 400a are sequentially formed on an entire surface of the substrate 100.

As shown in FIG. 4(D), a contact portion 350 is formed by removing predetermined portions of the semiconductor layer 300a and transparent conductive layer 400a. Thus, a plurality of patterns with the semiconductor layer 300 and transparent conductive layer 400b deposited in sequence are formed at fixed intervals by each contact portion 350 interposed in-between.

At this time, the contact portion 350 is positioned in contact with the first separating portion 250. More particularly, the predetermined portions of the semiconductor layer 300a and transparent conductive layer 400a on the front electrode 200 are removed so as to meet one end of the first separating portion 250 with one end of the contact portion 350. According as one end of the first separating portion 250 meets with one end of the contact portion 350, it is possible to minimize a dead zone in the solar cell.

In the same manner as the method according to the second embodiment of the present invention (See FIG. 3 D), in order to make the contact portion 350 and the first separating portion 250 partially overlapped at their predetermined portions, it is possible to remove the predetermined portion of the semiconductor layer 300a and transparent conductive layer 400a provided on the front electrode 200, and to remove the predetermined portion of the semiconductor layer 300a and transparent conductive layer 400a provided inside the first separating portion 250.

As shown in FIG. 4(E), a second separating portion 450 is formed by removing a predetermined portion of the transparent conductive layer 400b. Thus, the plurality of transparent conductive layers 400 are formed at fixed intervals by the contact portion 350 and second separating portion 450.

At this time, the predetermined portion of the transparent conductive layer 400b is removed so as to prevent the second separating portion 450 from being in contact with the contact portion 350.

Referring to the first embodiment of the present invention, when the rear electrode 500 is formed by the printing process (see FIG. 2 F) after forming the second separating portion 450 being in contact with the contact portion 350 (see FIG. 2 E), there is a possibility that the rear electrode 500 may be provided over the second separating portion 450 due to an error of the printing process. In this case, the rear electrodes 500, which have to be electrically separated by each unit cell, are electrically connected with one another, thereby causing a short.

In the third embodiment of the present invention, the second separating portion 450 is not in contact with the contact portion 350. Thus, even though the rear electrode 500 is provided over the second separating portion 450 due to the error of printing process, it is possible to minimize the occurrence of short between the rear electrodes 500. In order to minimize the occurrence of short, the plurality of second separating portions 450 may be formed between each of the rear electrodes 500.

As shown in FIG. 4(F), the rear electrode 500 is connected with the front electrode 200 through the contact portion 350.

The plurality of the rear electrodes 500 are formed at fixed intervals by each second separating portion 450 and the transparent conductive layer 400 next to the second separating portion 450 interposed in-between.

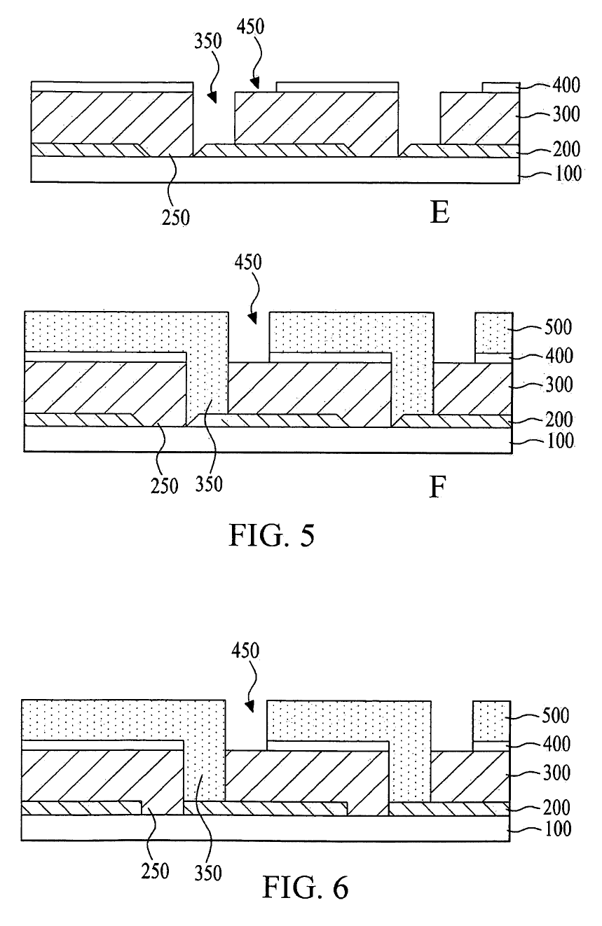

FIG. 5 (A to F) is a series of cross section views illustrating a method for manufacturing a thin film type solar cell according to the fourth embodiment of the present invention.

Except a step for forming a first separating portion 250, the method for manufacturing the thin film type solar cell according to the fourth embodiment of the present invention is identical to the method for manufacturing the thin film type solar cell according to the first embodiment of the present invention. Wherever possible, the same reference numbers will be used throughout the drawings to refer to the same or like parts as those of the aforementioned embodiment, and the detailed explanation for the same or like parts will be omitted.

First, as shown in FIG. 5(A), a front electrode layer 200a is formed on a substrate 100.

Next, as shown in FIG. 5(B), a first separating portion 250 is formed by removing a predetermined portion of the front electrode layer 200a. Accordingly, a plurality of front electrodes 200 are formed at fixed intervals by each first separating portion 250 interposed in-between.

At this time, the width of first separating portion 250 is gradually increased in the direction from its bottom to its top, whereby each lateral side of the first separating portion 250 is inclined as shown in the cross section view.

This inclined lateral side of the first separating portion 250 enables the increased contact surface between the front electrode 200 and a rear electrode to be described.

Next, as shown in FIG. 5(C), a semiconductor layer 300a and a transparent conductive layer 400a are sequentially formed on an entire surface of the substrate 100.

As shown in FIG. 5(D), a contact portion 350 is formed by removing predetermined portions of the semiconductor layer 300a and transparent conductive layer 400a. Accordingly, a plurality of patterns with the semiconductor layer 300 and transparent conductive layer 400b deposited in sequence are formed at fixed intervals by each contact portion 350 interposed in-between.

At this time, one lateral side of the contact portion 350 is positioned at one end portion of the bottom of the first separating portion 250, that is, one lateral side of the contact portion 350 meets with one end portion of the bottom of the first separating portion 250, wherein the bottom of the first separating portion 250 is relatively narrower than the top of the first separating portion 250. This structure enables the increased contact surface between the front electrode 200 and the rear electrode 500.

As shown in FIG. 5(E), a second separating portion 450 is formed by removing a predetermined portion of the transparent conductive layer 400b. Thus, the plurality of transparent conductive layers 400 are formed at fixed intervals by the contact portion 350 and second separating portion 450.

At this time, as shown in the drawing, the second separating portion 450 may be in contact with the contact portion 350. In the same manner as the method according to the third embodiment of the present invention (See FIG. 4 E), the second separating portion 450 may not be in contact with the contact portion 350.

As shown in FIG. 5(F), the rear electrode 500 is connected with the front electrode 200 through the contact portion 350.

The plurality of the rear electrodes 500 are formed at fixed intervals by each second separating portion 450 interposed in-between.

At this time, one lateral side of the first separating portion 250 is inclined through the process of FIG. 5(B), and one lateral side of the contact portion 350 is positioned at one end portion of the bottom of the first separating portion 250 through the process of FIG. 5(D), whereby the contact area between the front electrode 200 and the rear electrode 500 is increased.

FIG. 6 is a cross section view illustrating a thin film type solar cell manufactured by the first embodiment of the present invention.

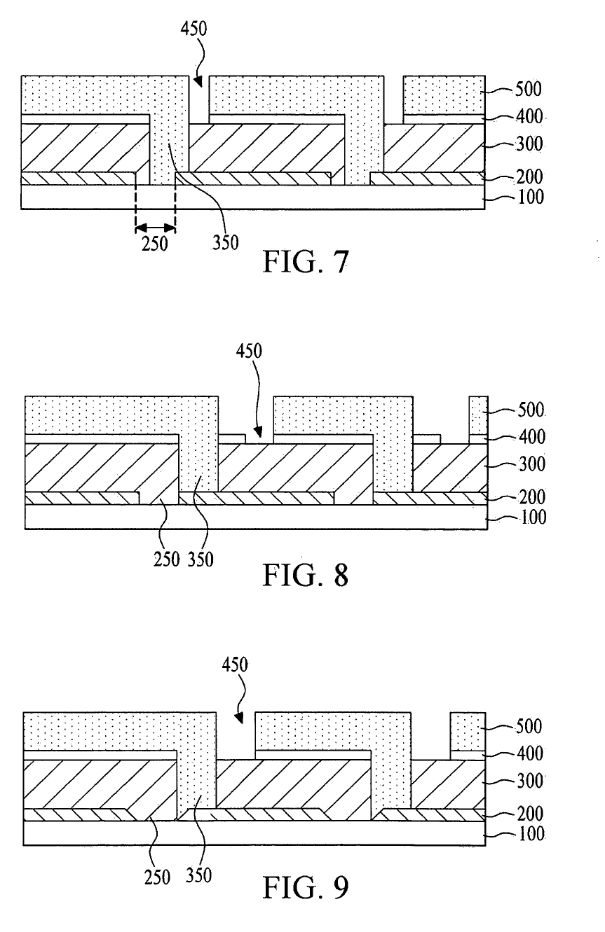

FIG. 7 is a cross section view illustrating a thin film type solar cell manufactured by the second embodiment of the present invention.

FIG. 8 is a cross section view illustrating a thin film type solar cell manufactured by the third embodiment of the present invention.

FIG. 9 is a cross section view illustrating a thin film type solar cell manufactured by the fourth embodiment of the present invention.

As seen collectively in FIGS. 6 to 9, the thin film type solar cell according to the present invention includes a substrate 100, a front electrode 200, a semiconductor layer 300, a transparent conductive layer 400, and a rear electrode 500.

The plurality of front electrodes 200 are formed on the substrate 100, wherein the plurality of front electrodes 200 are formed at fixed interval by each first separating portion 250 interposed in-between. In FIG. 9, the width of first separating portion 250 may be gradually increased in the direction from its bottom to its top, thereby enabling the lateral side of the first separating portion 250 to be inclined with reference to the vertical cross section. The front electrode 200 may have the uneven surface.

The plurality of semiconductor layers 300 are formed at fixed intervals by each contact portion 350 interposed in-between. As shown in FIGS. 6 and 8, one end of the contact portion 350 may meet one end of the first separating portion 250. As shown in FIG. 7, the contact portion 350 and the first separating portion 250 may be partially overlapped at their predetermined portions. As shown in FIG. 9, one lateral side of the contact portion 350 may be positioned at one end portion of the bottom of the first separating portion 250.

The plurality of transparent conductive layers 400 are formed at fixed intervals by the contact portion 350 and second separating portion 450. At this time, the second separating portion 450 may be in contact with the contact portion 350 as shown in FIGS. 6, 7, and 9, or the second separating portion 450 may not be in contact with the contact portion 350 as shown in FIG. 8. If the second separating portion 450 is not in contact with the contact portion 350, the plurality of second separating portions 450 may be provided between each of the rear electrodes 500.

The rear electrode 500 is connected with the front electrode 200 through the contact portion 350. The rear electrode 500 may be in contact with the upper surface of the front electrode 200 as shown in FIGS. 6 and 8, or the rear electrode 500 may be in contact with the upper and lateral surfaces of the front electrode 200 as shown in FIGS. 7 and 9.

Accordingly, the thin film type solar cell according to the present invention and the method for manufacturing the same has the following advantages.

First, the contact portion is positioned in contact with the first separating portion so that it is possible to decrease the dead zone, thereby resulting in the improved solar cell efficiency.

Also, the second separating portion is positioned in contact with the contact portion so that it is possible to decrease the dead zone, thereby resulting in the improved solar cell efficiency. Especially, the plurality of rear electrodes are formed at fixed intervals through the printing method instead of the related art method including the sequential steps for forming the rear electrode layer on the entire surface of the substrate and forming the second separating portions at fixed intervals by the laser-scribing process. Thus, it is possible to prevent the contact failure between the rear electrode and the front electrode even though the second separating portion is positioned in contact with the contact portion.

Also, it is possible to minimize the possibility for contamination in the substrate by decreasing the number of performing the laser-scribing process, and to improve the yield by decreasing the number of performing the cleaning process.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for manufacturing a thin film type solar cell comprising the steps of:
forming a plurality of front electrodes on a substrate, wherein the plurality of front electrodes are formed at fixed intervals by each first separating portion interposed in-between;
forming a semiconductor layer and transparent conductive layer on an entire surface of the substrate including the front electrodes;
forming a contact portion being in contact with the first separating portion by removing predetermined portions of the semiconductor layer and transparent conductive layer;
forming a second separating portion by removing a predetermined portion of the transparent conductive layer; and
forming a rear electrode connected with the front electrode through the contact portion.

2. The method of claim 1, wherein the step of forming the contact portion further comprises removing the predetermined portions of the semiconductor layer and transparent conductive layer provided on the front electrode so as to meet one end of the first separating portion with one end of the contact portion.

3. The method of claim 1, wherein the step of forming the contact portion further comprises removing the predetermined portions of the semiconductor layer and transparent conductive layer provided on the front electrode and removing the predetermined portions of the semiconductor layer and transparent conductive layer provided in the first separating portion, so as to make the first separating portion and the contact portion partially overlapped at their predetermined portions.

4. The method of claim 1, wherein the step of forming a plurality of front electrodes on a substrate further comprises the substeps of:
forming a front electrode layer on the substrate; and
forming the first separating portion by removing a predetermined portion of the front electrode layer.

5. The method of claim 4, wherein the substep of forming the first separating portion further comprises forming an inclined lateral side of the first separating portion by gradually increasing the width of first separating portion in the direction from its bottom to its top.

6. The method of claim 5, wherein the step of forming the contact portion further comprises making one lateral side of the contact portion positioned at one end portion of the bottom of the first separating portion, wherein the bottom of the first separating portion is relatively narrower than the top of the first separating portion.

7. The method of claim 1, wherein the step of forming the second separating portion further comprises removing the predetermined portion of the transparent conductive layer so as to make the second separating portion and the contact portion positioned to be in contact with each other.

8. The method of claim 1, wherein the step of forming the second separating portion further comprises removing the predetermined portion of the transparent conductive layer so as to make the second separating potion and the contact portion positioned not to be in contact with each other.

9. The method of claim 8, wherein the plurality of second separating portions are formed between each of the rear electrodes.

10. The method of claim 1, wherein the step of forming the rear electrode further comprises forming the rear electrode being in contact with the upper and lateral surfaces of the front electrode.

11. A thin film type solar cell comprising:
a substrate;
a plurality of front electrodes formed on the substrate at fixed intervals by each first separating portion interposed in-between;
a plurality of semiconductor layers formed at fixed intervals by each contact portion interposed in-between, the contact portion being in contact with the first separating portion;
a plurality of transparent conductive layers formed at fixed intervals by the contact portion and second separating portion; and
a rear electrode connected with the front electrode through the contact portion.

12. The thin film type solar cell of claim 11, wherein one end of the contact portion meets one end of the first separating portion.

13. The thin film type solar cell of claim 11, wherein the first separating portion and the contact portion are partially overlapped at their predetermined portions.

14. The thin film type solar cell of claim 11, wherein one lateral side of the first separating portion is inclined by gradually increasing the width of first separating portion in the direction from its bottom to its top.

15. The thin film type solar cell of claim 14, wherein one lateral side of the contact portion is positioned at one end portion of the bottom of the first separating portion, wherein the bottom of the first separating portion is relatively narrower than the top of the first separating portion.

16. The thin film type solar cell of claim 11, wherein the second separating portion is in contact with the contact portion.

17. The thin film type solar cell of claim 11, wherein the second separating portion is not in contact with the contact portion.

18. The thin film type solar cell of claim 17, wherein the plurality of second separating portions are formed between each of the rear electrodes.

19. The thin film type solar cell of claim 11, wherein the rear electrode is in contact with the upper and lateral surfaces of the front electrode.
